(19) United States
(12) Patent Application Publication
(10) Pub. No.: US 2025/0255049 A1
(43) Pub. Date: Aug. 7, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: FANWEI LIN, Xiamen (CN); POYANG CHANG, Xiamen (CN)

(21) Appl. No.: 19/187,365

(22) Filed: Apr. 23, 2025

Related U.S. Application Data
(63) Continuation of application No. PCT/CN2022/127897, filed on Oct. 27, 2022.

(51) Int. Cl. H10H 20/841; H10H 20/831

(52) U.S. Cl. CPC H10H 20/841; H10H 20/831

(57) ABSTRACT

A light-emitting diode includes: an epitaxial structure, having a first surface and a second surface opposite to each other and including a first semiconductor layer, a light-emitting layer and a second semiconductor layer sequentially stacked from the first surface to the second surface; a first electrical connecting layer, a first insulating layer, a first metal reflective layer and a barrier layer, disposed on a surface of the semiconductor layer facing away from the light-emitting layer; and an electrode, partially disposed on the first electrical connecting layer and electrically connected to the first semiconductor layer. In a region of the electrode, a distance between edge lines of the electrode and the barrier layer is smaller than a distance between the edge lines of the electrode and a light-emitting region of the epitaxial structure in an outer side of the edge line of the light-emitting region of the epitaxial structure.

### CROSS-REFERENCE TO RELATED APPLICATION

This application is a continuation of International Patent Application No. PCT/CN 2022/127897, filed on Oct. 27, 2022, which is herein incorporated by reference in its entirety.

### TECHNICAL FIELD

The disclosure relates to the technical field of semiconductor light-emitting devices, and more particularly to a light-emitting diode and a light-emitting device.

### BACKGROUND

Existing light-emitting diode (LED) chips can be divided into formal-chip structure, flip-chip structure and vertical-chip structure according to different packaging structures. In the formal-chip structure and the flip-chip structure, P and N electrodes in the LED chip are arranged horizontally on a same side. When current spreads horizontally, it is easy to produce current crowding, which causes localized overheating in the LED chip, thereby hindering the flow of current and making it difficult for the LED chip to dissipate heat quickly. Compared with the formal-chip structure and the flip-chip structure, the vertical LED chip has a short current spreading distance and good heat dissipation, and is suitable for carrying large current. The vertical LED chip has better light-emitting performance, and is often used in light-emitting devices in different lighting scenes.

In an epitaxial structure of the vertical LED chip, an ohmic contact part on the P electrode side is often provided with a silver (Ag) reflective layer to increase a light-emitting efficiency of the ohmic contact area and improve the overall light-emitting intensity of the LED chip. In order to prevent excessive diffusion of Ag, a barrier layer is disposed on the Ag reflective layer to control the diffusion of Ag within a specific region. However, the shielding of the barrier layer will reduce an amount of reflected light on the N electrode side of the vertical LED chip, affecting the light-emitting intensity of the vertical LED chip.

A literature with a Chinese patent publication NO. CN113345993A discloses a light-emitting diode, referring to FIG. 4 of the literature, in an electrode region 302-1 outside a light-emitting region of an epitaxial layer in the vertical LED, an edge line of the light-emitting region 900-1 of the epitaxial layer and an edge line of a metal barrier layer 500 (a second part 502 in the metal barrier layer) are basically coincident or overlapped, so that a corner between the metal barrier layer 500 and the light-emitting region 900-1 of the epitaxial layer in the electrode area 302-1 is too small, resulting in current concentration and affecting the normal performance and use of the light-emitting diode. In the vertical structure LED chip, a distance between an edge of an epitaxial structure (ISO) and an edge of the barrier layer in the electrode region is too small or overlapped, and an explosion point phenomenon caused by excessive current concentration is prone to occur between the edges of the electrode and the epitaxial structure, resulting in abnormal appearance of the LED chip and reduced infrared inspection (IR) yield.

Therefore, in the light-emitting diodes, how to set a barrier layer to prevent excessive diffusion of Ag in the reflective layer and ensure that there is a sufficient space between the edge of the barrier layer and the edge of the epitaxial structure in the electrode region to facilitate current spreading, to thereby improve the reliability of the light-emitting diodes and ensure that the chip has stable optoelectronic performance has become one of the technical problems that those skilled in the art need to solve urgently.

### SUMMARY

An embodiment of the disclosure provides a light-emitting diode, at least including an epitaxial structure, a first electrical connecting layer, a first insulating layer, a first metal reflective layer, a barrier layer, and an electrode. The epitaxial structure has a first surface and a second surface opposite to each other, and the epitaxial structure includes a first semiconductor layer, a light-emitting layer and a second semiconductor layer sequentially stacked in that order from the first surface to the second surface. The first electrical connecting layer is disposed on a surface of the first semiconductor layer facing away from the light-emitting layer. The first insulating layer is disposed on the surface of the first semiconductor layer facing away from the light-emitting layer, and covers at least a portion of a surface of the first electrical connecting layer. The first metal reflective layer is disposed on the first insulating layer, and covers at least a portion of the surface of the first electrical connecting layer. The barrier layer is disposed on the first insulating layer, and covers a surface and a sidewall of the first metal reflective layer. The electrode is partially disposed on the first electrical connecting layer, and is electrically connected to the first semiconductor layer. In a region of the electrode, a distance between an edge line of the electrode and an edge line of the barrier layer is smaller than a distance between the edge line of the electrode and the edge line of the light-emitting region of the epitaxial structure in a region where the electrode faces towards an edge line of a light-emitting region of the epitaxial structure.

In some embodiments, in the region of the electrode, a distance between the edge line of the barrier layer and the edge line of the light-emitting region of the epitaxial structure in an outer side of the edge line of the light-emitting region of the epitaxial structure is greater than or equal to 15 microns (μm).

In some embodiments, in the region of the electrode, the distance between the edge line of the barrier layer and the edge line of the light-emitting region of the epitaxial structure in the outer side of the edge line of the light-emitting region of the epitaxial structure is equal to 20 μm.

In some embodiments, in the region of the electrode, the distance between the edge line of the light-emitting region of the epitaxial structure and the edge line of the electrode is greater than or equal to 20 μm.

In some embodiments, a thickness of the first electrical connecting layer is in a range of 10 angstroms (Å) to 1500 Å, and the first electrical connecting layer is made of an oxide material.

In some embodiments, a thickness of the first metal reflective layer is in a range of 200 Å to 2000 Å.

In some embodiments, a thickness of the barrier layer is in a range of 500 Å to 10000 Å, and the barrier layer is made of at least one selected from the group consisting of gold (Au), chromium (Cr), titanium (Ti) and platinum (Pt), or a combination thereof.

In some embodiments, the barrier layer includes a first part and a second part in continuous. An edge line of the first part is at least partially located on an inner side of the edge line of the light-emitting region of the epitaxial structure, an edge line of the second part is located on the outer side of the edge line of the light-emitting region of the epitaxial structure, and the edge line of the second part is located on an outer side of the edge line of the electrode.

In some embodiments, in the region of the electrode, a distance between the edge line of the second part in the barrier layer and the edge line of the electrode is greater than or equal to 15 μm, and a distance between the edge line of the second part in the barrier layer and an edge line of the first metal reflective layer is in a range of 2 μm to 4 μm.

In some embodiments, in the region of the electrode, a distance between an edge line of the electrode and an edge line of the light-emitting region of the epitaxial structure in a nonlinear region (i.e., a current spreading region between the electrode and a non-light-emitting region of the epitaxial structure) where the electrode facing towards the light-emitting region of the epitaxial structure is greater than the distance between the edge line of the barrier layer and the edge line of the light-emitting region of the epitaxial structure, and the distance between the edge line of the electrode and the edge line of the light-emitting region of the epitaxial structure in the nonlinear region where the electrode faces towards the light-emitting region of the epitaxial structure is greater than the distance between the edge line of the light-emitting region of the epitaxial structure and the edge line of the electrode in the region where the electrode faces towards the light-emitting region of the epitaxial structure.

In some embodiments, the light-emitting diode further includes a second insulating layer and a second metal reflective layer. The second insulating layer is disposed on the barrier layer, and covers a surface and a sidewall of the barrier layer. The second metal reflective layer is disposed on the second insulating layer, and covers at least a surface of the second insulating layer.

In some embodiments, a thickness of the second metal reflective layer is in a range of 200 to 2000 Å.

In some embodiments, the light-emitting diode further defines an opening. The opening extends from the first surface of the epitaxial structure towards the second surface of the epitaxial structure and exposes a portion of the second semiconductor layer.

In some embodiments, the opening is at least two in quantity, and the at least two openings are continuously disposed on an edge region of the light-emitting region of the epitaxial structure. A distance between an edge line of each of the at least two openings and the edge line of the light-emitting region of the epitaxial structure is smaller than 30 μm. In other embodiments, the opening is at least two in quantity, and the at least two openings are equally spaced or unevenly spaced in the light-emitting region of the epitaxial structure and adjacent to a central region.

In some embodiments, the light-emitting diode further includes a substrate, and the first semiconductor layer in the epitaxial structure is bonded to the substrate through a bonding layer.

An embodiment of the disclosure provides a light-emitting device, which is manufactured by the aforementioned light-emitting diode. The light-emitting device can have a higher light-emitting brightness in a low current working environment and can meet the requirements of a continuous and stable low voltage working state.

Other features and advantages of the disclosure will be set forth in the following description, and in part will be apparent from the description, or may be learned by practicing the disclosure.

### BRIEF DESCRIPTION OF DRAWINGS

In order to more clearly describe technical solutions in embodiments of the disclosure or the in the related art, drawings required for descriptions in the embodiments or the related art are briefly introduced below. Apparently, the drawings described below are some of the embodiments of the disclosure. For those skilled in the art, other drawings can be obtained based on these drawings without creative work.

FIG. 1 illustrates a schematic sectional structural diagram of a light-emitting diode according to a first embodiment of the disclosure.

FIG. 2 illustrates a schematic structural diagram from a perspective of a top view of the light-emitting diode shown in FIG. 1.

FIG. 3 illustrates a schematic sectional structural diagram of a light-emitting diode according to a second embodiment of the disclosure.

FIG. 4 illustrates a schematic structural diagram from a perspective of a top view of the light-emitting diode shown in FIG. 3.

FIG. 5 illustrates a schematic diagram of a light-emitting device according to an embodiment of the disclosure.

### DESCRIPTION OF REFERENCE SIGNS

1—light-emitting diode; 10—substrate; 11—bonding layer; 20—epitaxial structure; 20a—first surface; 20b—second surface; 21—first semiconductor layer; 22—light-emitting layer; 23—second semiconductor layer; 24—opening; 201—light-emitting region; 30—first electrical connecting layer; 40—first insulating layer; 50—first metal reflective layer; 60—barrier layer; 61—first part; 62—second part; 70—second insulating layer; 80—second metal reflective layer; 81—electrode; D1, D2, D3, D4, D5, and D6—distance; 100—light-emitting device.

### DETAILED DESCRIPTION OF EMBODIMENTS

In order to make the purpose, technical solutions and advantages of the embodiments of the disclosure clearer, the technical solutions in the embodiments of the disclosure will be clearly and completely described below in conjunction with the drawings in the embodiments of the disclosure. The technical features designed in different embodiments of the disclosure described below can be combined with each other as long as they do not conflict with each other.

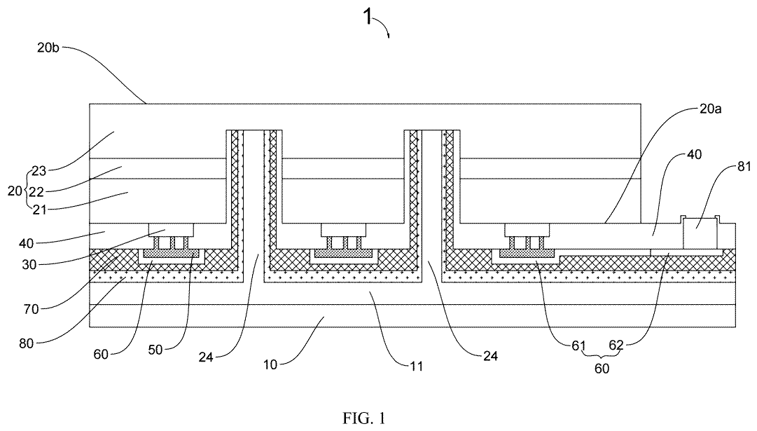

Referring to FIG. 1, FIG. 1 illustrates a schematic sectional structural diagram of a light-emitting diode according to a first embodiment of the disclosure. In order to achieve at least one of the advantages or other advantages, an embodiment of the disclosure provides a light-emitting diode 1, at least including an epitaxial structure 20, and a first electrical connecting layer 30, a first insulating layer 40, a first metal reflective layer 50, a barrier layer 60, and an electrode 81 disposed on the epitaxial structure 20. The epitaxial structure 20 has a first surface 20a and a second surface 20b opposite to each other, and the epitaxial structure 20 includes a first semiconductor layer 21, a light-emitting layer 22 and a second semiconductor layer 23 sequentially stacked in that order from the first surface 20a to the second surface 20b. At least the first electrical connecting layer 30, the first insulating layer 40, the first metal reflective layer 50 and the barrier layer 60 are sequentially disposed on a surface of the first semiconductor layer 21 facing away from the light-emitting layer 22 in that order. The electrode 81 is at least partially disposed on the first electrical connecting layer 30, and has a certain distance with the epitaxial structure 20. The electrode 81 is electrically connected to the first semiconductor layer 21. In an embodiment, the first metal reflective layer 50 and the barrier layer 60 are the first electrical connecting layer 30.

The epitaxial structure 20 can be formed on a substrate by a metal organic chemical vapor deposition (MOCVD) method, a molecular beam epitaxy (MBE) method, a hydride vapor deposition (HVPE) method, a physical vapor deposition (PVD) method or an ion plating method. Depending on the functions and purposes of the light-emitting diode 1 to be produced, the substrate can be a temporary growth substrate. After the epitaxial structure 20 is grown and formed, the epitaxial structure 20 is transferred to another substrate or a mounting substrate for subsequent processes.

The epitaxial structure 20 can provide light with a specific central emission wavelength, including but not limited to blue light, green light, red light, purple light or ultraviolet light. The epitaxial structure 20 can have a first surface 20a and a second surface 20b opposite to each other, and the epitaxial structure 20 includes a first semiconductor layer 21, a light-emitting layer 22 (or active layer 22) and a second semiconductor layer 23 sequentially stacked in that order from the first surface 20a to the second surface 20b, and the first semiconductor layer 21 and the second semiconductor layer 23 have opposite electrical properties.

In the illustrated embodiment, the first semiconductor layer 21 is a P-type semiconductor layer and the second semiconductor layer 23 is an N-type semiconductor layer, which is taken as an example for description. The disclosure is not limited thereto. In other embodiments, the first semiconductor layer 21 may be an N-type semiconductor layer and the second semiconductor layer 23 may be a P-type semiconductor layer.

In the illustrated embodiment, in the epitaxial structure 20, the first semiconductor layer 21 is a P-type semiconductor layer, which can provide holes to the light-emitting layer 22 under an action of a power source. In some embodiments, in the first semiconductor layer 21, the P-type semiconductor layer includes a P-type doped nitride layer, a P-type doped phosphide layer or a P-type doped arsenide layer. The P-type doped nitride layer, the P-type doped phosphide layer or the P-type doped arsenide layer may include one or more P-type impurities of group II elements. The P-type impurity may be one of magnesium (Mg), zinc (Zn), and beryllium (Be) or a combination thereof. The first semiconductor layer 21 may be a single-layer structure or a multi-layer structure, and the multi-layer structure may have different compositions.

The light-emitting layer 22 may be a quantum well (QW) structure. In some embodiments, the light-emitting layer 22 (or active layer 22) may be a multiple quantum well (MQW) structure alternately stacked by QW layers and quantum barrier layers. The light-emitting layer 22 may be a single QW structure or a MQW structure. In some embodiments, the light-emitting layer 22 may include a MQW structure of gallium nitride/aluminum gallium nitride (GaN/AlGaN), indium aluminum gallium nitride/indium aluminum gallium nitride (InAlGaN/InAlGaN), indium gallium nitride/aluminum gallium nitride (InGaN/AlGaN), indium gallium phosphide/aluminum gallium indium phosphide (GaInP/AlGaInP), indium gallium phosphide/aluminum indium phosphide (GaInP/AlInP) or indium gallium arsenic/aluminum indium gallium arsenic (InGaAs/AlInGaAs). In order to improve the light-emitting efficiency of the light-emitting layer 22, it can be achieved by changing a depth of the QW, the number of layers, thickness and/or other characteristics of paired QWs and quantum barriers in the light-emitting layer 22.

In the epitaxial structure 20, the second semiconductor layer 23 is an N-type semiconductor layer, which can provide electrons to the light-emitting layer 22 under the action of the power source. In some embodiments, in the second semiconductor layer 23, the N-type semiconductor layer includes an N-type doped nitride layer, an N-type doped phosphide layer or an N-type doped arsenide layer. The N-type doped nitride layer may include one or more N-type impurities of group IV elements. The N-type impurity may be one of silicon (Si), germanium (Ge), and tin (Sn), or a combination thereof. The second surface 20b of the epitaxial structure 20 is the same surface as a surface of the second semiconductor layer 23 facing away from the light-emitting layer 22. The arrangement of the epitaxial structure 20 is not limited thereto, and other types of arrangements may be selected according to the actual needs of the light-emitting diode 1.

The epitaxial structure 20 defines an opening 24. The opening 24 is at least one in quantity, and these openings 24 can be distributed in a light-emitting region 201 of the epitaxial structure 20. The opening 24 can be a hole, or a continuous groove, but is not limited thereto. The opening 24 can be a regular shape or an irregular shape. In the illustrated embodiment, the opening 24 is a groove or a hole defined by punching or digging from the first surface 20a towards the second surface 20b of the epitaxial structure 20. The opening 24 can expose a portion of the second semiconductor layer 23 in the epitaxial structure 20. The second semiconductor layer 23 exposed from the opening 24 can serve as an electrode contact surface of the second semiconductor layer 23, and the opening 24 can serve as an electrode hole of the second semiconductor layer 23. In the embodiment of FIG. 1, the openings 24 are mainly distributed in an inner region of the light-emitting region 201 of the epitaxial structure 20, which can increase the light-emitting amount of the light-emitting region 201 of the epitaxial structure 20 in the light-emitting diode 1.

The first surface 20a of the epitaxial structure 20 is the same surface as the surface of the first semiconductor layer 21 facing away from the light-emitting layer 22. The first electrical connecting layer 30 is disposed on the surface of the first semiconductor layer 21 facing away from the light-emitting layer 22. In the embodiment of FIG. 1, the first electrical connecting layer 30 is disposed on the first surface 20a of the epitaxial structure 20. The first electrical connecting layer 30 is at least disposed on the surface of the first semiconductor layer 21 (which is a P-type semiconductor layer in FIG. 1) facing away from the light-emitting layer 22. In order to further improve the uniformity of current spreading in the epitaxial structure 20, the first electrical connecting layer 30 may be distributed on a sidewall and a bottom of the opening 24 (not shown in the drawings).

In some embodiments, the first electrical connecting layer 30 may be a transparent conductive layer. The first electrical connecting layer 30 is made of an oxide material. The oxide material may have the characteristics of high transparency, high conductivity, and low contact resistance. For example, the first electrical connecting layer 30 may be one of indium tin oxide (ITO), indium zinc oxide (IZO), zinc oxide (ZNO), cadmium tin oxide (CTO), indium oxide (InO), indium (In) doped zinc oxide (ZNO), aluminum (Al) doped zinc oxide (ZNO), and gallium (Ga) doped zinc oxide (ZNO), or any combination thereof. The first electrical connecting layer 30 may serve as an ohmic contact layer of the first semiconductor layer 21, thereby ensuring that the light-emitting diode 1 has good electrical properties. A thickness of the first electrical connecting layer 30 is 10 Å to 1500 Å, which can ensure good current conduction and current spreading performance within the first semiconductor layer 21. At the same time, the first electrical connecting layer 30 has little effect on light-emitting absorption, and the light-emitting diode 1 has good light-emitting properties.

In order to enable the first electrical connecting layer 30 to achieve continuous and stable photoelectric performance in a region of the first semiconductor layer 21, the first insulating layer 40 is disposed on the surface of the first semiconductor layer 21 (which is a P-type semiconductor layer in FIG. 1) facing away from the light-emitting layer 22 to cover and protect the first electrical connecting layer 30. As shown in FIG. 1, the first insulating layer 40 covers a sidewall of the first electrical connecting layer 30 and a surface of the first electrical connecting layer 30 facing away from the first semiconductor layer 21. In some embodiments, the first insulating layer 40 may be made of one of silicon dioxide (SiO₂), silicon nitride (Si₃N₄), titanium dioxide (TiO₂), titanium monoxide (Ti₂O₃), titanium pentoxide (Ti₃O₅), tantalum pentoxide (Ta₂O₅), and zirconium dioxide (ZrO₂), or a combination thereof.

In some embodiments, the first insulating layer 40 may have a reflective function, and may reflect the light emitted by the first semiconductor layer 21, thereby enhancing the overall optical properties of the light-emitting diode 1. The first insulating layer 40 has a sufficient thickness, which can not only cover and protect the surface of the first electrical connecting layer 30 facing away from the first semiconductor layer 21, but also ensure that the sidewall of the first electrical connecting layer 30 is covered with the first insulating layer 40 of sufficient thickness, so that a portion of the first electrical connecting layer 30 exposed from the region of the first semiconductor layer 21 can be covered by the first insulating layer 40, ensuring that the current in the first semiconductor layer 21 at the first surface 20a of the epitaxial structure 20 can be uniformly spread or evenly distributed.

The first metal reflective layer 50 is disposed on the first insulating layer 40, which can improve the light reflection efficiency on a side of the first semiconductor layer 21. In some embodiments, the first electrical connecting layer 30 can serve as an ohmic contact layer of the first semiconductor layer 21, the first insulating layer 40 can expose a portion of the surface of the first electrical connecting layer 30, and the first metal reflective layer 50 can cover a surface of the first electrical connecting layer 30 exposed from the first insulating layer 40, thereby increasing the light reflection amount of the region of the first electrical connecting layer 30.

In some embodiments, the first metal reflective layer 50 mainly has a conductive function, which is beneficial to the spreading or conduction of current in the epitaxial structure 20. A thickness of the first metal reflective layer 50 is 200 Å to 2000 Å. A material of the first metal reflective layer 50 may have high activity and high reflectivity. The reflectivity of the material of the first metal reflective layer 50 is greater than 50%. In some embodiments, the material of the first metal reflective layer 50 may be a metal material with high reflectivity, such as Ag and Al. In the illustrated embodiment, the material of the first metal reflective layer 50 includes at least Ag to improve the light reflection efficiency of the region of the first electrical connecting layer 30, and increase the light-emitting amount of the light-emitting region 201 of the epitaxial structure 20, thereby improve the light-emitting efficiency of the light-emitting diode 1.

Since Ag has a high metal activity, it is easy to diffuse. In order to prevent excessive diffusion of Ag in the first metal reflective layer 50, the barrier layer 60 is disposed on the first insulating layer 40. The barrier layer 60 covers a surface and a sidewall of the first metal reflective layer 50 to form a covering protection for the first metal reflective layer 50, so that the Ag in the material of the first metal reflective layer 50 can be limited to the first metal reflective layer 50 and a region between the surface of the first metal reflective layer 50 and the surface of the first electrical connecting layer 30 for diffusion. As a result, the Ag in the material of the first metal reflective layer 50 will not migrate randomly on the first insulating layer 40 to affect the photoelectric performance of the light-emitting diode 1. A thickness of the barrier layer 60 is 500 Å to 10,000 Å. A material of the barrier layer 60 can be a low-reflectivity metal material. In some embodiments, the barrier layer 60 can be made of at least one selected from the group consisting of Au, Cr, Ti, and Pt, or a combination thereof.

In some embodiments, the light emitting diode 1 may further include a second insulating layer 70. The second insulating layer 70 may be disposed on the barrier layer 60 and cover a surface and a sidewall of the barrier layer 60 to provide a covering insulating protection for the barrier layer 60. A material of the second insulating layer 70 may be the same as that of the first insulating layer 40, or may be different from that of the first insulating layer 40. In some embodiments, the material of the second insulating layer 70 may be one of SiO₂, Si₃N₄, TiO₂, Ti₂O₃, Ti₃O₅, Ta₂O₅, and ZrO₂, or a combination thereof.

In some embodiments, the light-emitting diode 1 may further include a second metal reflective layer 80. The second metal reflective layer 80 is disposed on the second insulating layer 70 and covers at least a surface of the second insulating layer 70. A thickness of the second metal reflective layer 80 is 200 Å to 2000 Å. A material of the second metal reflective layer 80 has low activity and low reflectivity. The reflectivity of the material of the second metal reflective layer 80 is greater than 20%. The second metal reflective layer 80 can increase a light reflection efficiency of the light emitted from the barrier layer 60 through the second insulating layer 70, and reduce the absorption or shielding of the light-emitting amount of the light-emitting diode 1 by the barrier layer 60.

In some embodiments, the light-emitting diode 1 may further include a substrate 10. In the epitaxial structure 20, the first semiconductor layer 21 is bonded to the substrate 10 through a bonding layer 11. The substrate 10 may be a conductive substrate. In some embodiments, the conductive substrate may be a metal substrate, such as a Si substrate or a copper tungsten (CuW) substrate. In other embodiments, the conductive substrate may be an insulating substrate, such as an aluminum nitride (AlN) substrate. In an embodiment, the bonding layer 11 is made of metal, and the epitaxial structure 20 may be tightly connected to the substrate 10 through the metal bonding layer 11.

As shown in FIG. 1, in some embodiments, the sidewall of the opening 24 is at least covered with the first insulating layer 40, the second insulating layer 70, and the second metal reflective layer 80 (not shown in the drawings), and then a concave hole is defined in the opening 24. When the first semiconductor layer 20 in the epitaxial structure 20 is bonded to the substrate 10 through the metal bonding layer 11, a filling material may be disposed in the concave hole. In some embodiments, the filling material in the concave hole may be one of Ag, Al, Cr, nickel (Ni), Ti, tungsten (W), Pt, Sn, and Au, or a combination thereof. A connection surface region between the opening 24 and the second semiconductor layer 23 may be provided with the first electrical connecting layer 30 (not shown in the drawings) to facilitate the uniform spreading of the current in the second semiconductor layer 23. The sidewall of the opening 20 may also be provided with the first electrical connecting layer 30, which is conducive to the uniform distribution of the current in the epitaxial structure 20, thereby improving the overall electrical performance of the light-emitting diode 1.

In some embodiments, the light-emitting diode 1 may further include the electrode 81. The electrode 81 is electrically connected to the first semiconductor layer 21. The electrode 81 is at least partially disposed on the first electrical connecting layer 30 and close to the epitaxial structure 20, and there is a certain distance between the electrode 81 and the epitaxial structure 20. In the embodiment of FIG. 1, the electrode 81 is disposed above the barrier layer 60 and faces towards the light-emitting region 201 of the epitaxial structure 20. The barrier layer 60 is located below the electrode 81. As shown in FIG. 1, in some embodiments, the barrier layer 60 may include a first part 61 and a second part 62 in continuous. The first part 61 is at least partially located in the light-emitting region 201 of the epitaxial structure 20, and the second part 62 is located in the region of the electrode 81 on a nonlight-emitting region. A projection of the first electrical connecting layer 30 on the epitaxial structure 20 is located in a projection of the first part 61 of the barrier layer 60 on the epitaxial structure 20. A projection of the second part 62 of the barrier layer 60 on the epitaxial structure 20 is located outside an edge line of a projection of the epitaxial structure 20, and outside an edge line of a projection of the electrode 81 on the epitaxial structure 20.

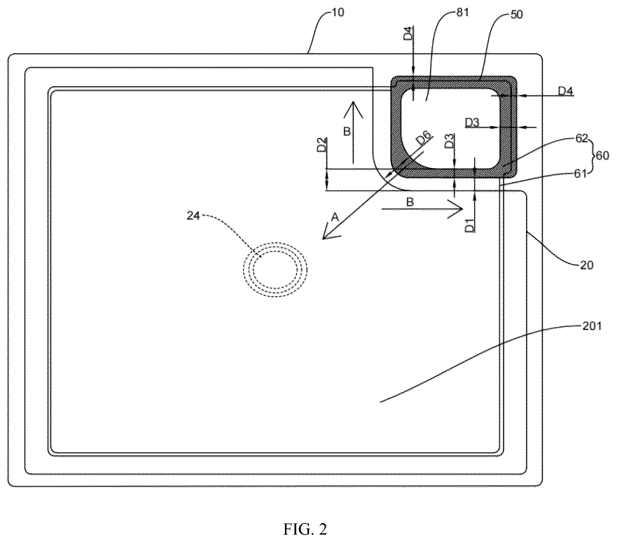

Referring to FIG. 2 in conjunction with FIG. 1, FIG. 2 illustrates a schematic structural diagram from a perspective of a top view of the light-emitting diode 1 shown in FIG. 1. In the embodiment of FIG. 2, the top view of the light emitting diode 1 shown in FIG. 1 is shown with the substrate 10 as a common projection surface, and the positional relationship among the epitaxial structure 20, the barrier layer 60 and the electrode 81 is further described. In the projection surface of the substrate 10, an edge line of the epitaxial structure 20 is within an edge line of the substrate 10. A region defined by the edge line of the epitaxial structure 20 is the light-emitting region 201 of the epitaxial structure 20, and an edge line of the electrode 81 is outside the edge line of the epitaxial structure 20. The electrode 81 is spaced a certain distance from the light-emitting region 201 of the epitaxial structure 20.

An edge line of the barrier layer 60 is distributed inside and outside the edge line of the epitaxial structure 20, and a portion of the edge line of the barrier layer 60 is distributed outside the edge line of the electrode 81. The edge line of the light-emitting region 201 of the epitaxial structure 20 is the edge line of the epitaxial structure 20. In the region of the electrode 81, a distance D3 between the edge line of the electrode 81 and the edge line of the barrier layer 60 is smaller than a distance D2 between the edge line of the electrode 81 and the edge line of the light-emitting region 201 of the epitaxial structure 20 in an outer side of the edge line of the light-emitting region 201 of the epitaxial structure 20.

The barrier layer 60 may include a first part 61 and a second part 62 in continuous. An edge line of the first part 61 is at least partially located inside the edge line of the epitaxial structure 20. In FIG. 2, the edge line of the first part 61 is located inside and outside the edge line of the epitaxial structure 20. An edge line of the second part 62 is located outside the edge line of the epitaxial structure 20 and outside the edge line of the electrode 81. In the region of the electrode 81, a distance D1 between the edge line (i.e., a connection between the first part 61 and the second part 62, or a corner of the barrier layer 60 located outside the electrode 81 in FIG. 2) of the second part 62 in the barrier layer 60 and the edge line of the light-emitting region 201 of the epitaxial structure 20 in the outer side of the edge line of the light-emitting region 201 of the epitaxial structure 20 is greater than or equal to 15 μm. In the region of the electrode 81, the distance D2 between the edge line of the epitaxial structure 20 and the edge line of the electrode 81 is greater than or equal to 20 μm. The size settings of the distances D1 and D2 ensure that the current can quickly spread to other directions within the light-emitting region 201 of the epitaxial structure 20 (as shown by an arrow B in FIG. 2) in the nonlinear region (as shown by an arrow A in FIG. 2) where the edge line of the electrode 81 faces towards the edge line of the light-emitting region 201 of the epitaxial structure 20.

The settings of the distances D1 and D2 ensures that the corner region or the nonlinear region (as shown by the arrow A in FIG. 2) where the edge line of the electrode 81 faces towards the edge line of the light-emitting region 201 of the epitaxial structure 20 has a sufficient distance, thereby preventing the current from being too concentrated and congested in the region to cause an explosion point phenomenon, and preventing breakdown due to excessive current density, which leads to a reduction in the yield of the light-emitting diode 1. The settings of the distances D1 and D2 can also improve the proportion of core failure caused by the tip effect.

As shown by the arrow A in FIG. 2, in the outer side of the light-emitting region 201 of the epitaxial structure 20, and in the corner region or the nonlinear region between the light-emitting region 201 of the epitaxial structure 20 and the electrode 81, a distance D6 between the edge line of the epitaxial structure 20 and the edge line of the electrode 81 is a current expansion distance of the region. Specifically, the distances D6>D1, and D6>D2, so that there is a sufficient distance for the current to spread quickly in the corner region or the nonlinear region where the electrode 81 faces towards the light-emitting region 201 of the epitaxial structure 20.

In test results of an actual finished product of the light-emitting diode 1, when the distance D1 between the edge line (the barrier layer 60 is located at the corner outside the light-emitting region 201 of the epitaxial structure 20) of the first part 61 of the barrier layer 60 and the edge line of the epitaxial structure 20 is greater than or equal to 15 μm, a yield of the light-emitting diode 1 is greatly improved, and the improvement can reach more than 10%. At the same time, the explosion point phenomenon of the barrier layer 60 at the corner outside the light-emitting region 201 of the epitaxial structure 20 is greatly reduced.

In an embodiment, in the region of the electrode 81, and in the outer side of the edge line of the epitaxial structure 20, the distance D1 between the edge line (the connection between the first part 61 and the second part 62, or the corner of the barrier layer 60 outside the light-emitting region 201 of the epitaxial structure 20 in FIG. 2) of the second part 62 of the barrier layer 60 and the edge line of the epitaxial structure 20 is 20 μm, and the distance D2 between the edge line of the epitaxial structure 20 and the edge line of the electrode 81 is 26 μm. Under this structural setting, the current in the corner region or the nonlinear region (as shown by the arrow A in FIG. 1) where the edge line of the electrode 81 faces towards the edge line of the epitaxial structure 20 can be instantly and quickly spread into the light-emitting region 201 of the epitaxial structure 20, thereby preventing instantaneous congestion when the current flows through the region and affecting the photoelectric performance of the light-emitting diode 1.

In the region of the electrode 81, a distance D3 between the edge line of the second part 62 of the barrier layer 60 and the edge line of the electrode 81 is greater than or equal to 15 μm, ensuring that outside the light-emitting region 201 of the epitaxial structure 20, there is a larger gap between the electrode 81 and the barrier layer 60 for current to flow quickly, thereby reducing the explosion point phenomenon caused by current concentration, which leads to poor electrical performance of the light-emitting diode 1.

In the region of the electrode 81, a distance D4 between the edge line of the second part 62 of the barrier layer 60 and an edge line of the first metal reflective layer 50 is 2 μm to 4 μm. This arrangement ensures that the barrier layer 60 has a sufficient thickness to cover the first metal reflective layer 50, preventing excessive migration of Ag in the first metal reflective layer 50, so as to improve the light reflection efficiency in the region of the first electrical connecting layer 30.

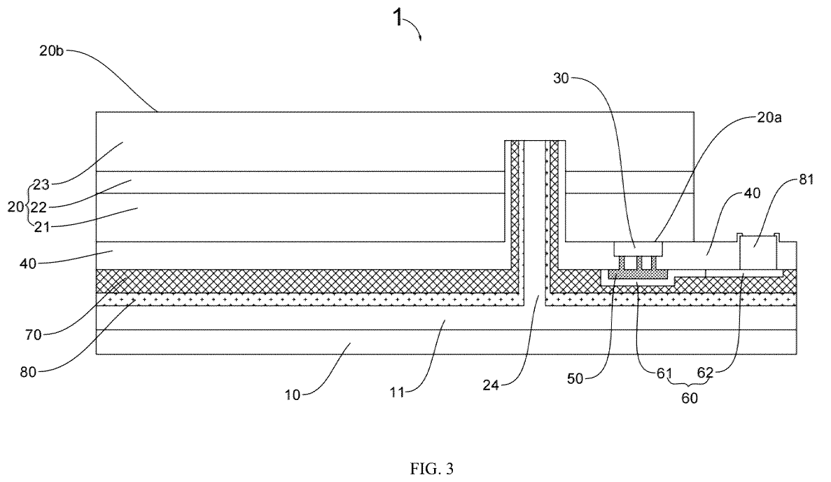

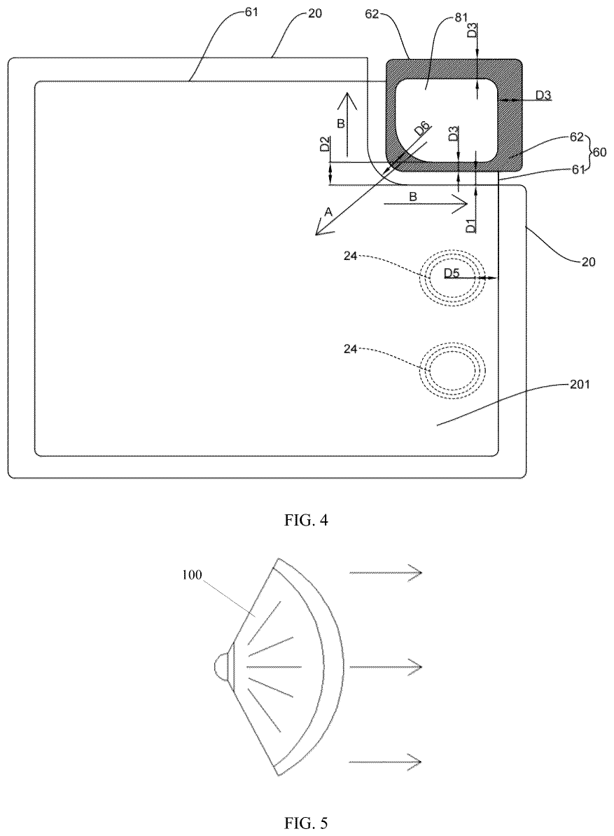

Referring to FIG. 3 and FIG. 4 in conjunction with FIG. 1, FIG. 3 illustrates a schematic sectional structural diagram of a light-emitting diode 1 according to a second embodiment of the disclosure, and FIG. 4 illustrates a schematic sectional diagram from a perspective of a top view of the light-emitting diode 1 shown in FIG. 3. The embodiment shown in FIG. 3 discloses a light-emitting diode 1, and its similarities with the embodiment of FIG. 1 are not repeated here, and the differences are described as follows.

In the embodiment of FIG. 3, the epitaxial structure 20 defines openings 24. Each opening 24 may be a hollow, a hole, or a continuous groove. The number of the openings 24 is at least two. Multiple openings 24 are continuously disposed in an edge region of the light-emitting region 201 of the epitaxial structure 20, which can increase the light-emitting amount of the edge region of the light-emitting region 201 of the epitaxial structure 20 in the light-emitting diode 1. Each opening 24 is a groove or hole defined by punching or digging from the first surface 20a towards the second surface 20b of the epitaxial structure 20. The opening 24 can expose a portion of the second semiconductor layer 23 in the epitaxial structure 20. The portion of the surface of the second semiconductor layer 23 exposed from the opening 24 can be used as an electrode contact surface of the second semiconductor layer 23, and the opening 24 can be used as an electrode hole (N-pole conductive hole) of the second semiconductor layer 23. The N-pole conductive hole (i.e., the opening 24) is closer to the edge region of the light-emitting region 201 of the epitaxial structure 20, which can make full use of the edge of the light-emitting region 20 of the epitaxial structure 20 to increase a light-emitting area of the epitaxial structure 20, thereby improving the light-emitting brightness of the light-emitting diode 1.

As shown in FIG. 4, the openings 24 are continuously arranged at the edge region of the light-emitting region 201 of the epitaxial structure 20. A distance D5 between an edge line of each opening 24 and the edge line of the light-emitting region 201 of the epitaxial structure 20 is less than 30 μm, which can ensure that there are more N-pole conductive holes at the edge region of the light-emitting region 201 of the epitaxial structure 20, thereby increasing the current spreading and the light-emitting amount. In addition, it can prevent the appearance of the edge region of the epitaxial structure 20 from being poor during the manufacturing process due to the small distance between the N-pole conductive holes and the edge region of the light-emitting region 201 of the epitaxial structure 20.

In the light-emitting diode 1, when its size is smaller, a contact area on a side of the N-type semiconductor layer becomes smaller, resulting in an increase in the voltage of the light-emitting diode 1. The openings 24 are continuously defined in the edge region of the light-emitting region 201 of the epitaxial structure 20, which can increase the contact area of the N-type semiconductor layer in the epitaxial structure 20 and reduce the voltage of the light-emitting diode 1.

In the light-emitting diode 1 provided by the disclosure, the setting of the barrier layer 60 can provide a covering protection for the first metal reflective layer 50 disposed above the first electrical connecting layer 30, thereby preventing excessive migration of Ag in the first metal reflective layer 50, which facilitates the uniform spreading of the current on a side of the first semiconductor layer 21 (which is a P-type semiconductor layer in FIG. 3) in the epitaxial structure 20, and improve the overall electrical performance of the light-emitting diode 1. In the region of the electrode 81, and in the outer side of the light-emitting region 201 of the epitaxial structure 20, the distance D1 between the edge line of the epitaxial structure 20 and the edge line of the barrier layer 60 is greater than or equal to 15 μm, thus, there is a sufficient distance for the current to pass quickly when the current flows through this region, thereby reducing the explosion point phenomenon caused by current concentration, improving the product yield, and greatly improving the light-emitting brightness of the light-emitting diode 1. Under high current density, compared with existing products, the light-emitting diode 1 provided by the disclosure has higher brightness and relatively lower voltage.

In order to achieve at least one of the above advantages or other advantages, an embodiment of the disclosure provides a light-emitting device 100, which is manufactured by the light-emitting diode 1 as described above. The light-emitting device 100 has a high light-emitting brightness in a low-current working environment and can meet the requirements of a continuous and stable low-voltage working state. The light-emitting device 100 can be applied to various smart wearable devices to ensure that the smart wearable devices can maintain a stable working state that meets the requirements, so that the smart wearable devices can continuously and stably provide monitoring information of the user's physical health indicators.

Finally, it should be noted that the above embodiments are only used to illustrate the technical solutions of the disclosure, rather than to limit it. Although the disclosure has been described in detail with reference to the aforementioned embodiments, those skilled in the art should understand that they can still modify the technical solutions described in the aforementioned embodiments, or replace some or all of the technical features therein by equivalents. However, these modifications or replacements do not cause the essence of the corresponding technical solutions to deviate from the scope of the technical solutions of the embodiments of the disclosure.

What is claimed is:

1. A light-emitting diode, comprising:
an epitaxial structure, having a first surface and a second surface opposite to each other; wherein the epitaxial structure comprises a first semiconductor layer, a light-emitting layer and a second semiconductor layer sequentially stacked in that order from the first surface to the second surface;
a first electrical connecting layer, disposed on a surface of the first semiconductor layer facing away from the light-emitting layer;
a first insulating layer, disposed on the surface of the first semiconductor layer facing away from the light-emitting layer, and covering at least a portion of a surface of the first electrical connecting layer;
a first metal reflective layer, disposed on the first insulating layer, and covering at least a portion of the surface of the first electrical connecting layer;
a barrier layer, disposed on the first insulating layer, and covering a surface and a sidewall of the first metal reflective layer; and
an electrode, partially disposed on the first electrical connecting layer, and electrically connected to the first semiconductor layer; and
wherein in a region of the electrode, a distance between an edge line of the electrode and an edge line of the barrier layer is smaller than a distance between the edge line of the electrode and the edge line of the light-emitting region of the epitaxial structure in a region where the electrode faces towards an edge line of a light-emitting region of the epitaxial structure.

2. The light-emitting diode as claimed in claim 1, wherein in the region of the electrode, a distance between the edge line of the barrier layer and the edge line of the light-emitting region of the epitaxial structure in an outer side of the edge line of the light-emitting region of the epitaxial structure is greater than or equal to 15 microns (μm).

3. The light-emitting diode as claimed in claim 1, wherein in the region of the electrode, the distance between the edge line of the light-emitting region of the epitaxial structure and the edge line of the electrode is greater than or equal to 20 μm.

4. The light-emitting diode as claimed in claim 1, wherein a thickness of the first electrical connecting layer is in a range of 10 angstroms (Å) to 1500 Å, and the first electrical connecting layer is made of an oxide material.

5. The light-emitting diode as claimed in claim 1, wherein a thickness of the first metal reflective layer is in a range of 200 Å to 2000 Å.

6. The light-emitting diode as claimed in claim 1, wherein a thickness of the barrier layer is in a range of 500 Å to 10000 Å, and the barrier layer is made of at least one selected from the group consisting of gold (Au), chromium (Cr), titanium (Ti) and platinum (Pt), or a combination thereof.

7. The light-emitting diode as claimed in claim 1, wherein the barrier layer comprises a first part and a second part in continuous; an edge line of the first part is at least partially located on an inner side of the edge line of the light-emitting region of the epitaxial structure, an edge line of the second part is located on an outer side of the edge line of the light-emitting region of the epitaxial structure, and the edge line of the second part is located on an outer side of the edge line of the electrode.

8. The light-emitting diode as claimed in claim 7, wherein in the region of the electrode, a distance between the edge line of the second part in the barrier layer and the edge line of the electrode is greater than or equal to 15 μm, and a distance between the edge line of the second part in the barrier layer and an edge line of the first metal reflective layer is in a range of 2 μm to 4 μm.

9. The light-emitting diode as claimed in claim 1, wherein in the region of the electrode, a distance between an edge line of the electrode and an edge line of the light-emitting region of the epitaxial structure in a nonlinear region where the electrode faces towards the light-emitting region of the epitaxial structure is greater than a distance between the edge line of the barrier layer and the edge line of the light-emitting region of the epitaxial structure, and the distance between the edge line of the electrode and the edge line of the light-emitting region of the epitaxial structure in the nonlinear region where the electrode faces towards the light-emitting region of the epitaxial structure is greater than the distance between the edge line of the light-emitting region of the epitaxial structure and the edge line of the electrode in the region where the electrode faces towards the light-emitting region of the epitaxial structure.

10. The light-emitting diode as claimed in claim 1, further comprising:
a second insulating layer, disposed on the barrier layer, and covering a surface and a sidewall of the barrier layer; and
a second metal reflective layer, disposed on the second insulating layer, and covering at least a surface of the second insulating layer.

11. The light-emitting diode as claimed in claim 10, wherein a thickness of the second metal reflective layer is in a range of 200 to 2000 Å.

12. The light-emitting diode as claimed in claim 1, wherein the light-emitting diode further defines an opening, and the opening extends from the first surface of the epitaxial structure towards the second surface of the epitaxial structure and exposes a portion of the second semiconductor layer.

13. The light-emitting diode as claimed in claim 12, wherein the opening is at least two in quantity, the at least two openings are continuously disposed on an edge region of the light-emitting region of the epitaxial structure, and a distance between an edge line of each of the at least two openings and the edge line of the light-emitting region of the epitaxial structure is smaller than 30 μm.

14. The light-emitting diode as claimed in claim 1, further comprising a substrate, wherein the first semiconductor layer in the epitaxial structure is bonded to the substrate through a bonding layer.

15. A light-emitting device, wherein the light-emitting device is manufactured by the light-emitting diode as claimed in claim 1.
